(19) United States
(12) Patent Application Publication
(10) Pub. No.: US 2011/0240360 A1
(43) Pub. Date: Oct. 6, 2011

(54) CONCEALED-TYPE RETRACTABLE EXTENSION CORD ORGANIZING STRUCTURE

(76) Inventor: Po-Chou LIN, Tucheng City (TW)

(21) Appl. No.: 12/752,536

(22) Filed: Apr. 1, 2010

(51) Int. Cl. H05K 5/00; B65H 75/30; B65H 75/48

(52) U.S. Cl. 174/520; 242/385.4

(57) ABSTRACT

A concealed-type retractable extension cord organizing structure includes a junction box having a front cover plate provided with a fixed socket and a rewinding control button; and at least one movable socket movably mounted on the front cover plate and connected at an inner end to a reel via a power cord. The power cord is normally invisibly wound up in a space provided in the reel. The movable socket and power cord can be pulled out with fingers to an extended position and locked thereto for use. When the rewinding control button is pushed, the power cord is retracted into the junction box and rewound around the reel, so that the movable socket becomes flush with the front cover plate again and the power cord is concealed behind the front cover plate and neatly wound up without occupying extra space.

### FIELD OF THE INVENTION

The present invention relates to an extension cord organizing structure, and more particularly to a concealed-type retractable extension cord organizing structure that includes a socket movably mounted on a front cover plate of a junction box and connected to a power cord invisibly hidden in the junction box. The socket and the power cord can be pulled out and locked to a desired extended position for use, and the power cord is retractable to rewind around a reel in the junction box when the socket is not in use.

### BACKGROUND OF THE INVENTION

Following the constantly upgraded living quality due to various kinds of advanced scientific technologies, every modern family is now equipped with many electrically operated devices of different functions. There are chances these electrically operated devices are not located at positions with easily accessible power sockets. As a matter of fact, most of the currently available power sockets are fixedly mounted on walls. Therefore, extension cords are needed for users to obtain power supply in a mobile manner.

One of the simplest types of extension cords includes a socket, a suitable length of power cord connected at an end to the socket, and a plug connected to the other end of the power cord. To use this simple type of extension cord, just plug the plug on one end of the power cord in a general wall socket and move the socket on the other end of the power cord to a desired position for an electrically operated device to plug in the socket and obtain required power supply. While the above-described conventional extension cord allows a user to easily and quickly obtain power supply from a distant wall socket, the user has to pay additional cost to purchase the extension cord for use. Sometimes, the power cord for the extension cord is too long or too short and does not meet the user's actual need. When multiple extension cords are being used at the same time, these extension cords tend to disorderly disperse on the floor in a room and become tangled with one another, making a room using these extension cords in an unpleasant condition. Further, the long extension cords dispersed on the floor would also dangerously trip users and other people in the room.

It is therefore tried by the inventor to develop a concealed-type retractable extension cord organizing structure, with which an extension cord can be conveniently pulled out of a junction box for use at any time or be retracted into the junction box to save room when the extension cord is not in use. Thus, the problems with the conventional extension cord can be overcome.

### SUMMARY OF THE INVENTION

A primary object of the present invention is to provide a concealed-type retractable extension cord organizing structure, which includes a junction box having a front cover plate provided with a fixed socket and a rewinding control button; and at least one movable socket being movably mounted on the front cover plate and connected at an inner end to a reel via a power cord. The power cord is normally invisibly wound up in a space provided in the reel, so that the power cord is invisibly hidden in the reel. The movable socket and the power cord connected thereto can be pulled out with fingers to a desired extended position and locked thereto for use. When the movably socket is not in use and the rewinding control button is pushed, the power cord is retracted into the junction box and rewound around the reel, so that the movable socket becomes flush with the front cover plate again and the power cord is concealed behind the front cover plate and neatly wound up without occupying extra space. Therefore, the present invention is convenient for use without occupying a large space and ensures a pleasing and neat outer appearance in a room.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a perspective view showing an outer appearance of a concealed-type retractable extension cord organizing structure according to the present invention;

FIG. 2 is a sectioned top plan view showing an interior arrangement of the concealed-type retractable extension cord organizing structure of the present invention according to a first embodiment thereof;

FIG. 3 is a sectioned top plan view showing an interior arrangement of the concealed-type retractable extension cord organizing structure of the present invention according to a second embodiment thereof;

FIG. 4 shows a socket connected to a power cord is pulled out from the concealed-type retractable extension cord organizing structure of the present invention for use;

FIG. 5 shows the out-pulled socket and power cord shown in FIG. 4 are retracted into the concealed-type retractable extension cord organizing structure of the present invention; and

FIG. 6 is a partially cutaway view of the concealed-type retractable extension cord organizing structure of the present invention according to a third embodiment thereof.

### DETAILED DESCRIPTION OF THE PREFERRED EMBODIMENTS

The present invention will now be described with some preferred embodiments thereof. For the purpose of easy to understand, elements that are the same in the preferred embodiments are denoted by the same reference numerals.

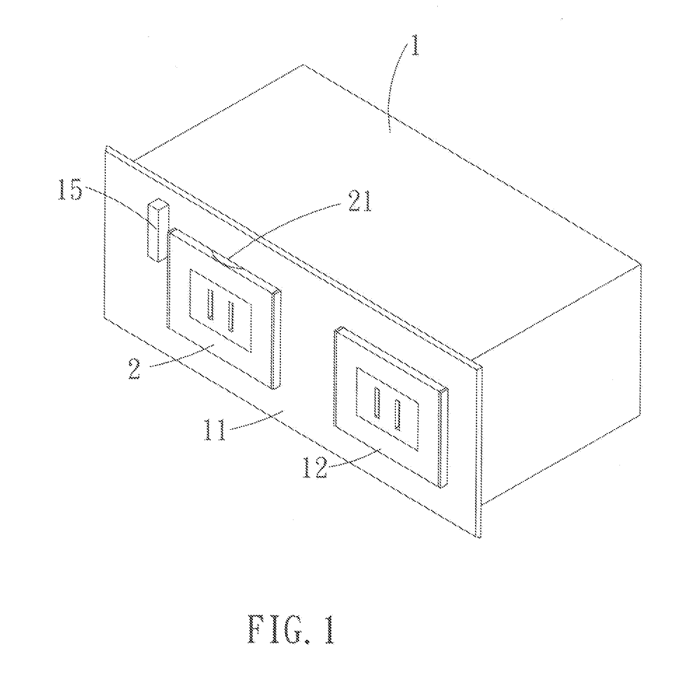

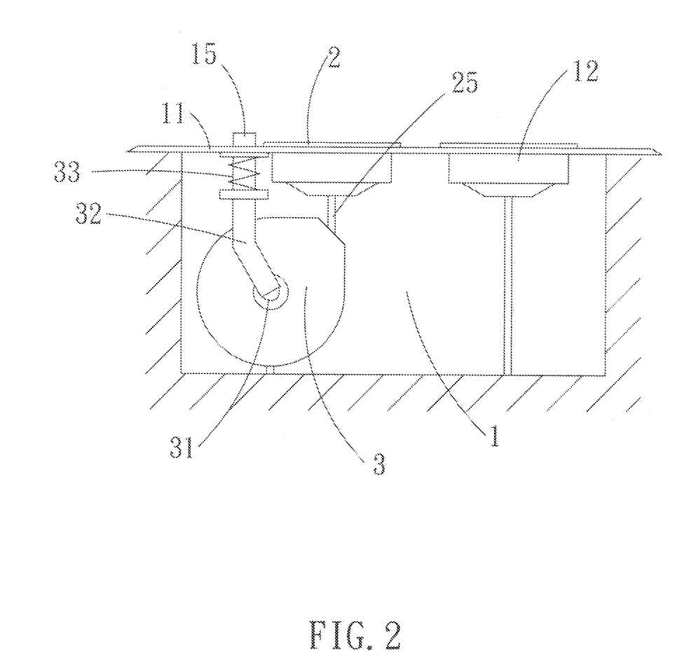

Please refer to FIG. 1 that is a perspective view showing an outer appearance of a concealed-type retractable extension cord organizing structure according to the present invention, and to FIG. 2 that is a sectioned top plan view showing an interior arrangement of the concealed-type retractable extension cord organizing structure of the present invention according to a first embodiment thereof. As shown, the concealed-type retractable extension cord organizing structure of the present invention includes a junction box 1 having a front cover plate 11, on which a fixed socket 12 and a rewinding control button 15 are provided; and at least one movable socket 2 movably mounted on the front cover plate 11 to connect at an inner end to a reel 3 via a length of retractable power cord 25. The power cord 25 is connected to the movable socket 2 and can be wound up in a space provided in the reel 3, so that the power cord 25 is invisibly hidden in the reel 3.

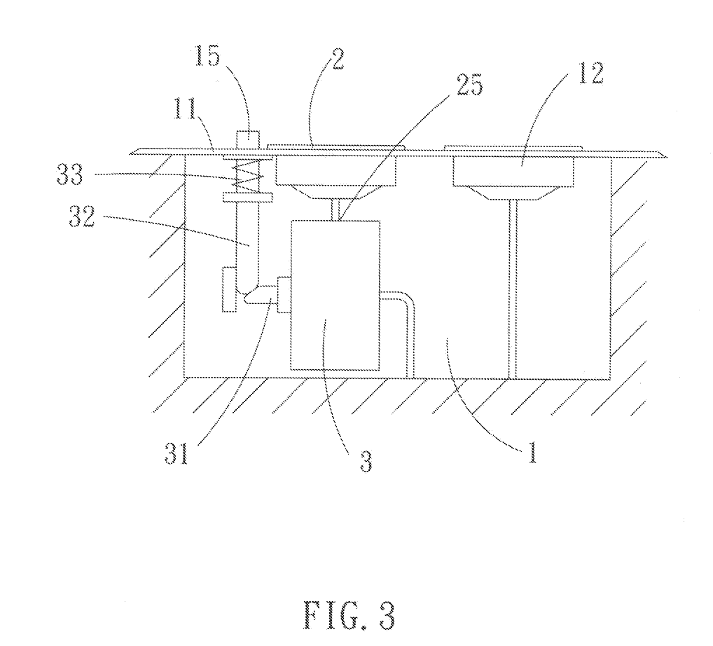

As can be seen in FIG. 1, the movable socket 2 is provided at an upper edge with a finger slot 21. When a user applies a pull force at the finger slot 21, the movable socket 2 along with the retractable power cord 25 connected thereto can be conveniently pulled out from the front cover plate 11 of the junction box 1. In the first embodiment of the present invention as shown in FIG. 2, the reel 3 with the movable socket 2 connected thereto is arranged in the junction box 1 in parallel with the front cover plate 11. According to a second embodiment of the present invention as shown in FIG. 3, the reel 3 is arranged in the junction box 1 in perpendicular to the front cover plate 11.

As can be seen in both FIGS. 2 and 3, the reel 3 is further provided with a release button 31, which is connected to a rear end of a push bar 32. The push bar 32 has a front end connected to the rewinding control button 15, and a spring 33 fitted around an intermediate section of the push bar 32. When the rewinding control button 15 is pushed, the push bar 32 is caused to move backward and push against the release button 31, so that the reel 3 is released for rewinding the power cord 25 therearound.

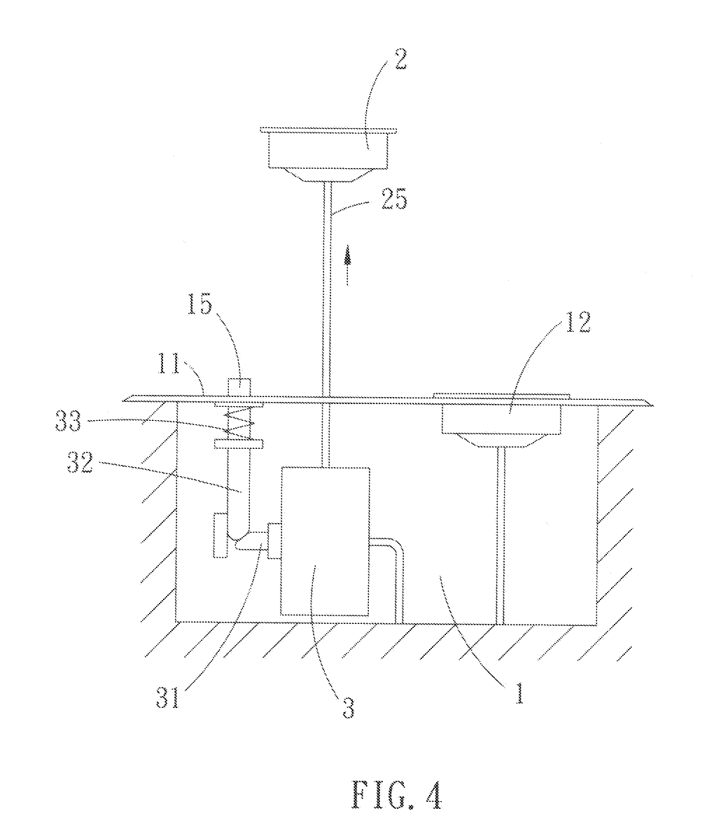

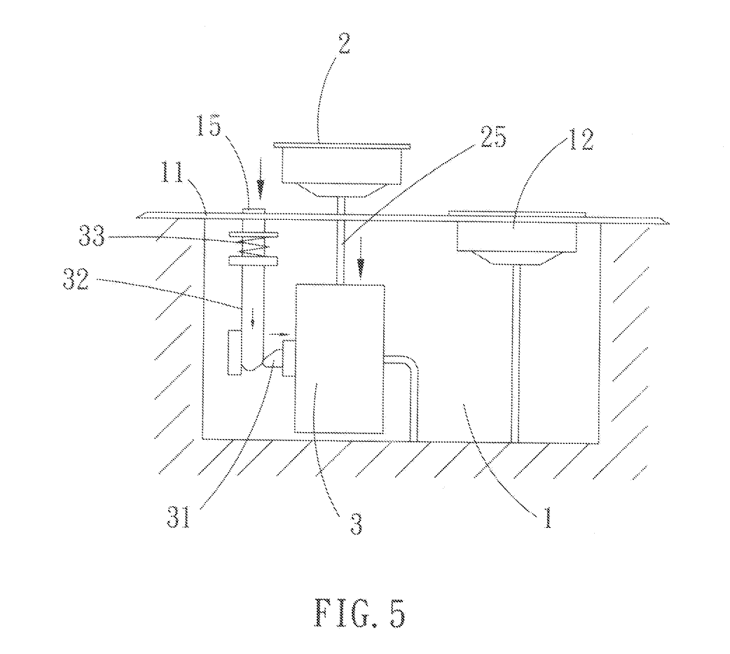

As can be seen in FIGS. 2 to 5, the junction box 1 is installed in a general power outlet provided in a building structure. The movable socket 2 is provided on the front cover plate 11 in advance, and the power cord 25 having a suitable length is wound and invisibly hidden in the reel 3 when the movable socket 2 is not in use. Please refer to FIG. 4. When it is desired to use the movable socket 2, the user simply pulls the movable socket 2 at the finger slot 21, and the movable socket 2 can be conveniently located at an extended position relative to the junction box 1. When the movable socket 2 is pulled to a desired extended position and released, the reel 3 can automatically lock the out-pulled power cord 25 to the extended position and prevent the same from automatically retracting and rewinding. On the other hand, when the movable socket 2 is not in use, the user can simply push the rewinding control button 15, as shown in FIG. 5. At this point, the push bar 32 is caused to move backward and press against the release button 31, enabling the reel 3 to rewind the power cord 25. Meanwhile, the movable socket 2 is brought to move toward the front cover plate 11 until the power cord 25 is completely concealed behind the front cover plate 11, and the movable socket 2 is returned to its home position and become flush with the front cover plate 11 again, as shown in FIGS. 2 and 3. Therefore, with the present invention, a retractable extension cord formed from the movable socket 2 and the power cord 25 can be neatly organized without occupying too much space.

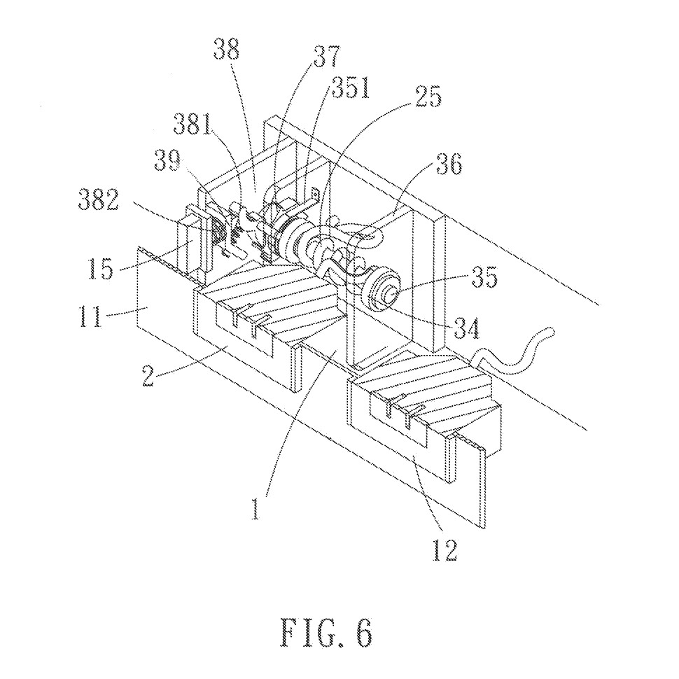

FIG. 6 is a partially cutaway view of the concealed-type retractable extension cord organizing structure of the present invention according to a third embodiment thereof. In the third embodiment, the reel 3 includes a rotary disc 34, a rotary shaft 35, a pair of support plates 36, and a toothed rotary disc 37. The rotary shaft 35 has a volute spring 351 mounted thereon, and the power cord 25 is wound around the rotary shaft 35. The rotary disc 34 and the toothed rotary disc 37 are separately connected to two ends of the rotary shaft 35 and then rested on the pair of support plates 36. A release element 38 is connected to the toothed rotary disc 37. The release element 38 includes a stop block 381 and a spring 382. A push bar 39 is provided between the release element 38 and the rewinding control button 15. When the rewinding control button 15 is pushed, the push bar 39 is caused to press against the release element 38, bringing the latter to release from the toothed rotary disc 37 and allowing the reel 3 to rewind the out-pulled power cord 25.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A concealed-type retractable extension cord organizing structure, comprising:
a junction box having a front cover plate, and the front cover plate being provided thereon with a fixed socket and a rewinding control button; and
at least one movable socket being movably mounted on the front cover plate and connected at an inner end to a reel via a length of power cord; and the power cord connected to the movable socket being normally wound up in a space provided in the reel, so that the power cord is invisibly hidden in the reel;
whereby the movable socket can be freely pulled out from the junction box to an extended position for use; when the movable socket is pulled to a desired extended position and released, the reel automatically locks the power cord to the extended position and prevents the out-pulled power cord from automatically retracting and rewinding; and when the rewinding control button is pushed, the out-pulled power cord is retracted into the junction box and rewound around the reel, so that the movable socket is returned to and becomes flush with the front cover plate again and the power cord is concealed behind the front cover plate.

2. The concealed-type retractable extension cord organizing structure as claimed in claim 1, wherein the movable socket is provided at an edge thereof with a finger slot accessible by a user.

3. The concealed-type retractable extension cord organizing structure as claimed in claim 1, wherein the reel includes a release button connected to a rear end of a push bar; the push bar having a front end connected to the rewinding control button and an intermediate section having a spring fitted therearound; whereby when the rewinding control button is pushed, the push bar is caused to move backward and press against the release button, bringing the reel to rewind the out-pulled power cord therearound.

4. The concealed-type retractable extension cord organizing structure as claimed in claim 2, wherein the reel includes a release button connected to a rear end of a push bar; the push bar having a front end connected to the rewinding control button and an intermediate section having a spring fitted therearound; whereby when the rewinding control button is pushed, the push bar is caused to move backward and press against the release button, bringing the reel to rewind the out-pulled power cord therearound.

5. The concealed-type retractable extension cord organizing structure as claimed in claim 3, wherein the reel connected to the movable socket is arranged in the junction box in parallel with the front cover plate.

6. The concealed-type retractable extension cord organizing structure as claimed in claim 4, wherein the reel connected to the movable socket is arranged in the junction box in parallel with the front cover plate.

7. The concealed-type retractable extension cord organizing structure as claimed in claim 3, wherein the reel connected to the movable socket is arranged in the junction box perpendicular to the front cover plate.

8. The concealed-type retractable extension cord organizing structure as claimed in claim 4, wherein the reel connected to the movable socket is arranged in the junction box perpendicular to the front cover plate.

9. The concealed-type retractable extension cord organizing structure as claimed in claim 1, wherein the reel includes a rotary disc, a rotary shaft, a pair of support plates, and a toothed rotary disc; the rotary shaft having a volute spring mounted thereon, and the power cord being wound around the rotary shaft; the rotary disc and the toothed rotary disc being separately connected to two ends of the rotary shaft and then rested on the pair of support plates; a release element being connected to the toothed rotary disc, and including a stop block and a spring; and a push bar being provided between the release element and the rewinding control button; whereby when the rewinding control button is pushed, the push bar is caused to press against the release element, bringing the latter to release from the toothed rotary disc and allowing the reel to rewind the power cord.
